(19) United States
(12) Patent Application Publication
(10) Pub. No.: US 2019/0041918 A1
(43) Pub. Date: Feb. 7, 2019

(54) SPINE ASSEMBLY FOR A COMPUTING SYSTEM WITH MULTIPLE COMPUTING PARTS

(71) Applicant: Intel Corporation, Santa Clara, CA (US)

(72) Inventors: Denica N. Larsen, Portland, OR (US); Prosenjit Ghosh, Portland, OR (US); Murali Veeramoney, Portland, OR (US); Praveen Vishakantaiah, Hillsboro, OR (US)

(21) Appl. No.: 16/020,830

(22) Filed: Jun. 27, 2018

(51) Int. Cl. G06F 1/16; H05K 5/02

(52) U.S. Cl. CPC G06F 1/1681; G06F 1/1632; G06F 1/1618; H05K 5/0226; G06F 1/1683; G06F 1/1698; G06F 1/1635

(57) ABSTRACT

Embodiments include apparatuses, methods, and systems for computing. A computing apparatus may include a first computing part and a second computing part. The first computing part and the second computing part may be attached to a spine assembly. The first computing part may include a first electronic interface and a first mechanical attachment coupler to be coupled to the spine assembly, while the second computing part may include a second electronic interface and a second mechanical attachment coupler to be coupled to the spine assembly. The first computing part or the second computing part may rotate around a rotation hinge of the spine assembly from a first position to a second position. Other embodiments may also be described and claimed.

### FIELD

Embodiments of the present invention relate generally to the technical fields of computing, and more particularly to a computing system with multiple computing parts.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

A computing device or a computing system, e.g., a laptop computer, a smartphone, a tablet, a detachable 2-in-1 device, an embedded device, or other devices, may be a device that can accept software for various purposes and applications. A computing device may include various components, e.g., a logic unit, a control unit, memory, and input and output devices (collectively termed I/O). Current computing devices or systems may be designed purposely for certain functions. Users may be limited to the configurations as built by the manufacturers of the computing devices or systems.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates an example computing system including a first computing part and a second computing part to be attached to a spine assembly, in accordance with various embodiments.

FIG. 2 illustrates another example computing system including a first computing part and a second computing part to be attached to a spine assembly, in accordance with various embodiments.

FIG. 3 illustrates various configurations of a computing system formed by attaching a first computing part and a second computing part to a spine assembly, in accordance with various embodiments.

FIG. 4 illustrates an example rotation hinge of a spine assembly, in accordance with various embodiments.

FIG. 5 illustrates an example mechanical attachment coupler of a spine assembly, in accordance with various embodiments.

FIG. 6 illustrates an example computing apparatus including three or more computing parts, where two computing parts may be attached to a spine assembly, in accordance with various embodiments.

FIG. 7 illustrates an example computing apparatus including three or more computing parts, where two computing parts may be attached to a spine assembly, in accordance with various embodiments.

FIG. 8 illustrates an example process for forming a computing system by attaching a first computing part and a second computing part to a spine assembly, in accordance with various embodiments.

FIG. 9 illustrates an example device suitable for use to practice various aspects of the present disclosure, in accordance with various embodiments.

### DETAILED DESCRIPTION

Many different computing devices and systems have been developed in recent years. Current computing devices may be designed for certain limited functions, and pre-configured without being interchangeable with other devices. At most, a 2-in-1 system may include two parts, e.g., a tablet and a keyboard, to act as either a tablet or a clamshell laptop when the keyboard is attached. Users may be limited to the one or two configurations of a computing device built by the device manufacturer. When a user desires additional functionality, additional devices may be purchased. For examples, if a user wants an artist pad, a separated device, e.g., a Wacom's drawing tablet, may be purchased. For eReader or eWriter functionality, a Kindle from Amazon® or a digital ePaper from SONY® may be acquired. As a result, a user may own multiple devices, such as a laptop, an ereader, a tablet, an ewriter, or more, for different functionalities. Those devices may not be tightly integrated together, and may have different form factors with different user interfaces.

Embodiments herein may present a computing apparatus including three or more computing parts, where a first computing part and a second computing part selected from the three or more computing parts may be attached to a spine assembly to form a computing system for a specific functionality. The spine assembly may enable a seamless integration of multiple computing parts to allow the end user the flexibility of configuring systems to fit the usages. In addition, the three or more computing parts of the computing apparatus may share a same or similar form factors or user interfaces. In addition, the three or more computing parts of the computing apparatus may be made by different manufacturers. For example, one computing part may include a display screen to be attached to the spine assembly, while other computing part, e.g., a computing part for a 2-in-1 system, or a computing part for a laptop, may be selected and attached to the spine assembly, so that the display screen may be used in either situation.

In embodiments, a spine assembly for a computing system includes a first attachment subassembly, a second attachment subassembly, and a rotation hinge coupled to the first attachment subassembly and the second attachment subassembly. The first attachment subassembly includes a first mechanical attachment coupler and a first electronic interface, where the first electronic interface and the first mechanical attachment coupler may be coupled to a first computing part of the computing system. The second attachment subassembly includes a second mechanical attachment coupler and a second electronic interface, where the second electronic interface and the second mechanical attachment coupler may be coupled to a second computing part of the computing system. In addition, the first attachment subassembly or the second attachment subassembly can rotate around the rotation hinge from a first position to a second position.

In embodiments, a computing apparatus includes a first computing part and a second computing part. The first computing part and the second computing part may be attached to a spine assembly. The first computing part includes a first electronic interface and a first mechanical attachment coupler to be coupled to the spine assembly, while the second computing part includes a second electronic interface and a second mechanical attachment coupler to be coupled to the spine assembly. The first computing part or the second computing part may rotate around a rotation hinge of the spine assembly from a first position to a second position.

In embodiments, a method for forming a computing system may include attaching a first computing part to a spine assembly. The first computing part includes a first electronic interface to be coupled to a first electronic interface of the spine assembly, and a first mechanical attachment coupler to be coupled to a first mechanical attachment coupler of the spine assembly. The method may further include attaching a second computing part to the spine assembly. The second computing part includes a second electronic interface to be coupled to a second electronic interface of the spine assembly, and a second mechanical attachment coupler to be coupled to a second mechanical attachment coupler of the spine assembly. The first computing part or the second computing part may rotate around a rotation hinge of the spine assembly from a first position to a second position.

In embodiments, a computing apparatus includes three or more computing parts. A first computing part and a second computing part may be selected from the three or more computing parts to be attached to a spine assembly. The first computing part may include a first electronic interface and a first mechanical attachment coupler to be coupled to the spine assembly. The second computing part may include a second electronic interface and a second mechanical attachment coupler to be coupled to the spine assembly. The first computing part or the second computing part may rotate around a rotation hinge of the spine assembly from a first position to a second position.

In the description to follow, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Operations of various methods may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiments. Various additional operations may be performed and/or described operations may be omitted, split or combined in additional embodiments.

For the purposes of the present disclosure, the phrase “A or B” and “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used hereinafter, including the claims, the term “unit,” “engine,” “module,” or “routine” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

The terms “coupled with” and “coupled to” and the like may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. By way of example and not limitation, “coupled” may mean two or more elements or devices are coupled by electrical connections on a printed circuit board such as a motherboard, for example. By way of example and not limitation, “coupled” may mean two or more elements/devices cooperate and/or interact through one or more network linkages such as wired and/or wireless networks. By way of example and not limitation, a computing apparatus may include two or more computing devices “coupled” on a motherboard or by one or more network linkages.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

As used herein, the term “interface” or “interface circuitry” may refer to, is part of, or includes circuitry providing for the exchange of information between two or more components or devices. The term “interface circuitry” may refer to one or more hardware interfaces (for example, buses, input/output (I/O) interfaces, peripheral component interfaces, network interface cards, and/or the like).

Some embodiments may be used in conjunction with various devices and systems, for example, a communication system, a communication device, a wireless communication system, a wireless communication device, a wired communication device, a wired communication system, a personal computer (PC), a desktop computer, a mobile computer, a laptop computer, a notebook computer, an Ultrabook™ computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wired or wireless modem, a video device, an audio device, an audio-video (AN) device, a wired or wireless network, a wireless area network, a wireless video area network (WVAN), a local area network (LAN), a wireless LAN (WLAN), a personal area network (PAN), a wireless PAN (WPAN), a wireless wide area network (WWAN), and the like.

Some embodiments may be used in conjunction with devices and/or networks operating in accordance with existing web real-time communication standards, IEEE 802.11 standards, wireless-gigabit-alliance (WGA) specifications, wireless fidelity (WiFi) alliance (WFA) peer-to-peer (P2P) specifications, 3rd generation partnership project (3GPP), 3GPP long term evolution (LTE), any current and/or future versions and/or derivatives thereof, and the like.

Some embodiments may be used in conjunction with one way and/or two-way radio communication systems, cellular radio-telephone communication systems, a mobile phone, a cellular telephone, a wireless telephone, a personal communication systems (PCS) device, a PDA device which incorporates a wireless communication device, a mobile or portable global positioning system (GPS) device, a device which incorporates a GPS receiver or transceiver or chip, a device which incorporates an RFID element or chip, a multiple input multiple output (MIMO) transceiver or device, a single input multiple output (SIMO) transceiver or device, a multiple input single output (MISO) transceiver or device, a device having one or more internal antennas and/or external antennas, digital video broadcast (DVB) devices or systems, multi-standard radio devices or systems, a wired or wireless handheld device, e.g., a smartphone, a wireless application protocol (WAP) device, or the like.

Some embodiments may be used in conjunction with one or more types of wireless communication signals and/or systems, for example, radio frequency (RF), infrared (IR), frequency-division multiplexing (FDM), orthogonal FDM (OFDM), time-division multiplexing (TDM), time-division multiple access (TDMA), extended TDMA (E-TDMA), general packet radio service (GPRS), extended GPRS, code-division multiple access (CDMA), wideband CDMA (WCDMA), CDMA 2000, single-carrier CDMA, multi-carrier CDMA, multi-carrier modulation, discrete multi-tone (DMT), Bluetooth®, global positioning system (GPS), Wi-Fi, Wi-Max, ZigBee™, ultra-wideband (UWB), global system for mobile communication (GSM), 2G, 2.5G, 3G, 3.5G, 4G, fifth generation (5G) mobile networks, 3GPP, long term evolution (LTE), LTE advanced, enhanced data rates for GSM evolution (EDGE), or the like. Other embodiments may be used in various other wired and/or wireless devices, systems and/or networks.

The term “wireless device,” as used herein, includes, for example, a device capable of wireless communication, a communication device capable of wireless communication, a communication station capable of wireless communication, a portable or non-portable device capable of wireless communication, or the like. In some embodiments, a wireless device may be or may include a peripheral that is integrated with a computer, or a peripheral that is attached to a computer. In some embodiments, the term “wireless device” may optionally include a wireless service.

The term “communication device”, as used herein, includes, for example, a device capable of wireless and/or wired communication, a communication device capable of wireless and/or wired communication, a communication station capable of wireless and/or wired communication, a portable or non-portable device capable of wireless and/or wired communication, or the like. In some embodiments, a communication device may be or may include a peripheral that is integrated with a computer, or a peripheral that is attached to a computer.

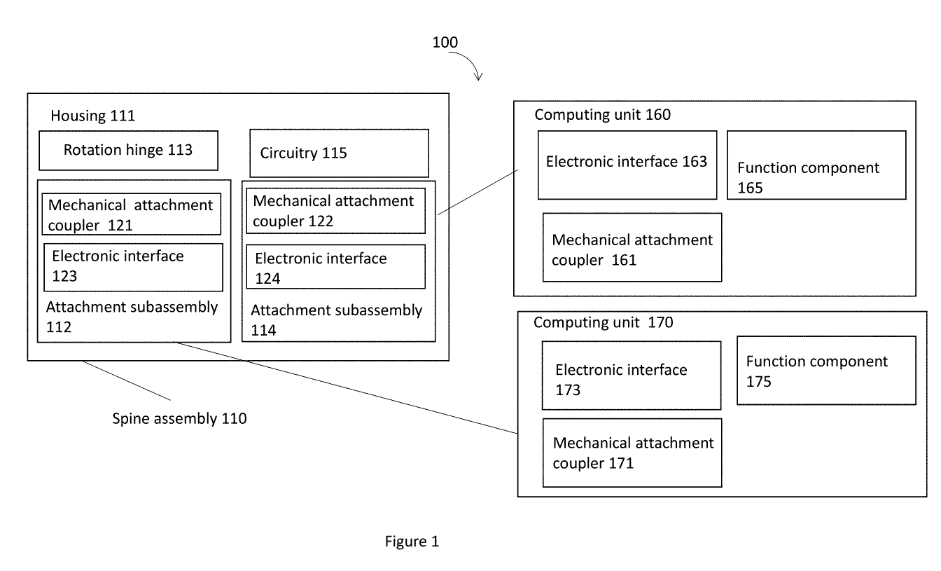

FIG. 1 illustrates an example computing system 100 including a computing part 160 and a computing part 170 to be attached to a spine assembly 110, in accordance with various embodiments. For clarity, features of the computing system 100, the computing part 160, the computing part 170, and the spine assembly 110 may be described below as an example for understanding an example computing system, a first computing part, a second computing part, and a spine assembly. It is to be understood that there may be more or fewer components included in the computing system 100, the computing part 160, the computing part 170, and the spine assembly 110. Further, it is to be understood that one or more of the devices and components within the computing system 100, the computing part 160, the computing part 170, and the spine assembly 110 may include additional and/or varying features from the description below, and may include any devices and components that one having ordinary skill in the art would consider and/or refer to as the devices and components of a computing system including a first computing part and a second computing part to be attached to a spine assembly.

In embodiments, the computing system 100 is decomposed into three components: the computing part 160 and the computing part 170 to be attached to the spine assembly 110. As such, the assembly of the computing system 100 is different from conventional 2-in-1 systems or other like computing devices, where a device is decomposed into at most two components. By attaching two different computing parts, e.g., the computing part 160 and the computing part 170, to the spine assembly 110, a user may configure the computing system 100 into a multitude of configurations by attaching different computing parts to the spine assembly 110. The computing part 160, the computing part 170, and the spine assembly 110 may be made by different manufacturers, and acquired by a user at a different time. Additionally and alternatively, the computing part 160, the computing part 170, and the spine assembly 110 may be made by a same manufacturer, and acquired by a user at a same time.

In embodiments, the spine assembly 110 includes an attachment subassembly 112 and an attachment subassembly 114. The attachment subassembly 112 includes a mechanical attachment coupler 121 and an electronic interface 123. The attachment subassembly 112 is any physical structure that holds the mechanical attachment coupler 121 and the electronic interface 123 together. The mechanical attachment coupler 121 refers to any mechanical connections between the spine assembly 110 and a computing part, e.g., the computing part 160 or the computing part 170. Similarly, the electronic interface 123 refers to any electronic connections, directly or indirectly through multiple other components, between the spine assembly 110 and a computing part, e.g., the computing part 160 or the computing part 170. The attachment subassembly 114 includes a mechanical attachment coupler 122 and an electronic interface 124. The attachment subassembly 114 is any physical structure that holds the mechanical attachment coupler 122 and the electronic interface 124 together. The spine assembly 110 further includes a rotation hinge 113 coupled to the attachment subassembly 112 and the attachment subassembly 114. In addition, the spine assembly 110 may include a housing 111, which may include the rotation hinge 113, the attachment subassembly 112, or the attachment subassembly 114. In some embodiments, the attachment subassembly 112, or the attachment subassembly 114 may be an integrated part of the housing 111. The spine assembly 110 may also include a circuitry 115 coupled to the housing 111.

In embodiments, the computing part 160 may include a mechanical attachment coupler 161 and an electronic interface 163 to be coupled to the spine assembly 110. The computing part 170 may include a mechanical attachment coupler 171 and an electronic interface 173 to be coupled to the spine assembly 110. The computing part 160 may further include a function component 165, and the computing part 170 may further include a function component 175. The function component 165 may refer to any device components that perform the intended functions for the computing part 160, and the function component 175 may refer to any device components that perform the intended functions for the computing part 170.

In embodiments, the mechanical attachment coupler 121 and the electronic interface 123 may be coupled to the mechanical attachment coupler 161 and the electronic interface 163 of computing part 160. Similarly, the mechanical attachment coupler 122 and the electronic interface 124 may be coupled to the mechanical attachment coupler 171 and the electronic interface 173 of computing part 170. The circuitry 115 of the spine assembly 110 may be coupled to the computing part 160 or the computing part 170. In detail, the circuitry 115 of the spine assembly 110 may communicate through the electronic interface 123 and the electronic interface 163 of computing part 160, or through the electronic interface 124 and the electronic interface 173 of computing part 170.

In embodiments, the attachment subassembly 112 or the attachment subassembly 114 may rotate around the rotation hinge 113 from a first position to a second position. When attached to the spine assembly 110, the computing part 160 or the computing part 170 may rotate around the rotation hinge 113 of the spine assembly 110 from a first position to a second position.

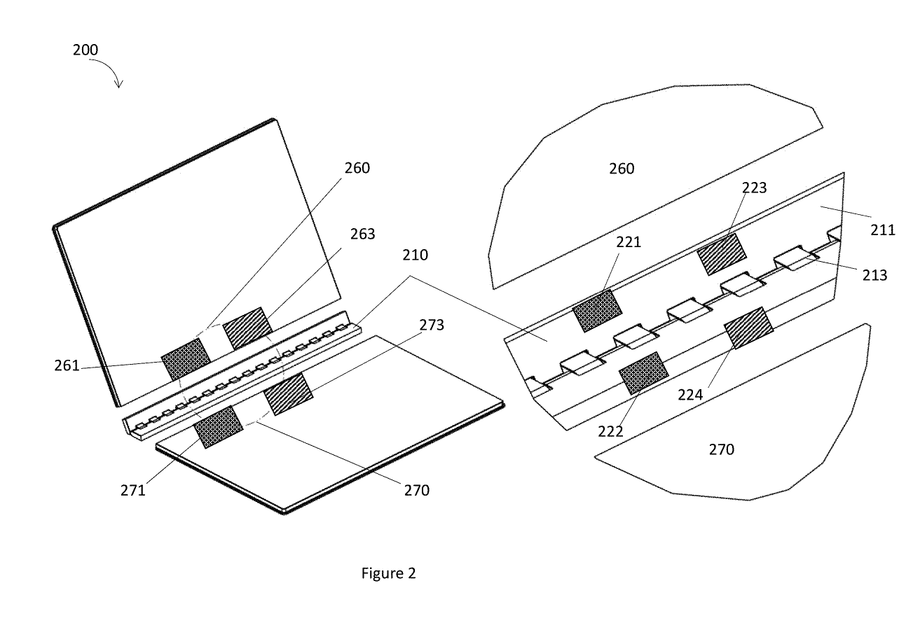

FIG. 2 illustrates another example computing system 200 including a computing part 260 and a computing part 270 to be attached to a spine assembly 210, in accordance with various embodiments. In embodiments, the computing system 200, the computing part 260, the computing part 270, and the spine assembly 210 may be examples of the computing system 100, the computing part 160, the computing part 170, and the spine assembly 110, respectively as shown in FIG. 1.

In this example, the computing system 200 includes the computing part 260 and the computing part 270 to be attached to the spine assembly 210. In embodiments, the computing system 200 may include a third computing part, not shown, to be attachable to the spine assembly 210 in lieu of either the computing part 260 or the computing part 270. The additional third computing part to be attachable to the spine assembly 210 may allow a user to configure the computing system 200 for different functions, providing more flexibility than the current computing devices and systems.

In embodiments, the spine assembly 210 includes a mechanical attachment coupler 221 and an electronic interface 223 on one side of the spine assembly 210, and a mechanical attachment coupler 222 and an electronic interface 224 at another side of the spine assembly 210. The spine assembly 210 further includes a rotation hinge 213 between the side and the other side of the spine assembly 210 (i.e., at the middle of the spine assembly 210). A housing 211 may include the rotation hinge 213, the mechanical attachment coupler 221, the electronic interface 223, the mechanical attachment coupler 222, and the electronic interface 224. The spine assembly 210 may also include a circuitry, not shown. When attached to the spine assembly 210, the computing part 260 or the computing part 270 may rotate around the rotation hinge 213 of the spine assembly 210 from a first position to a second position.

The computing part 260 includes a mechanical attachment coupler 261 and an electronic interface 263 to be coupled to the spine assembly 210. The computing part 270 includes a mechanical attachment coupler 271 and an electronic interface 273 to be coupled to the spine assembly 210. In embodiments, the mechanical attachment coupler 221 and the electronic interface 223 may be coupled to the mechanical attachment coupler 261 and the electronic interface 263 of computing part 260. Similarly, the mechanical attachment coupler 222 and the electronic interface 224 may be coupled to the mechanical attachment coupler 271 and the electronic interface 273 of computing part 270.

In embodiments, the computing system 200 may be one selected from a 2-in-1 system, an artist pad, an eReader, a wearable device, a smartphone, a computer tablet, a laptop, a game controller, a set-top box, an infotainment console, or an IoT device, or an in-vehicle automotive system. In other words, the computing system 200 may perform the functions of a 2-in-1 system, an artist pad, an eReader, a wearable device, or other devices, while implemented in a different design with two computing parts to be attached to the spine assembly 210.

In embodiments, the computing part 260 or the computing part 270 may include a computing part selected from a processor, a storage device, an input or output peripheral device, or a power source. For example, the computing part 260 or the computing part 270 may include an input or output peripheral device selected from a keyboard, a printer, a speaker, a projector, a sound card, a video card, a camera, a video, a graphics tablet, a scanner, a joystick, a microphone, a mouse, a stylus, a virtual keyboard, a clock, a trackball, a resistive touchscreen, a capacitive touchscreen, an infrared touchscreen, an optical touchscreen, a display, a light-emitting diode (LED) display, a liquid crystal display (LCD), a thin film transistor liquid crystal display (TFT-LCD), a digital light processing (DLP) display, a plasma display, an electroluminescent panel, an organic light-emitting diode (OLED) display, or an electronic paper.

In embodiments, the electronic interface 263, the electronic interface 273, the electronic interface 223, or the electronic interface 224 may include an interface according to a near field communication (NFC) protocol, a wireless personal area network (WPAN) protocol, a mobile body area networks (MBAN) protocol, an infrared protocol, a Bluetooth® protocol, a ZigBee protocol, a Z-Wave protocol, a dedicated short range communications (DSRC) protocol, a universal serial bus (USB) protocol, a Miracast protocol, a wireless display (WiDi) protocol, a high-bandwidth digital content protection (HDCP) protocol, a user input back channel (UIBC), a mobile industry processor interface display serial interface (MIPI-DSI) protocol, a high-definition multimedia interface (HDMI) protocol, a display port (DP) protocol, a serial peripheral interface (SPI) protocol, a scalable coherent interface (SCI) protocol, a small computer system interface (SCSI) protocol, a peripheral component interconnect (PCI) protocol, or an inter-integrated circuit (I²C) protocol.

In embodiments, the rotation hinge 213 may include a hinge selected from a base bracket hinge, a damping hinge, a display hinge, a friction hinge, a revolving hinge, a clamshell hinge, a free stop hinge, a 45° hinge, a 90° hinge, or a 360 degree micro hinge including orbital axles, mounting brackets, and a slider pin. The mechanical attachment coupler 261, the mechanical attachment coupler 271, the mechanical attachment coupler 221, or the mechanical attachment coupler 222, may include a component selected from a detachable latch, a pin coupler, or a quick coupler.

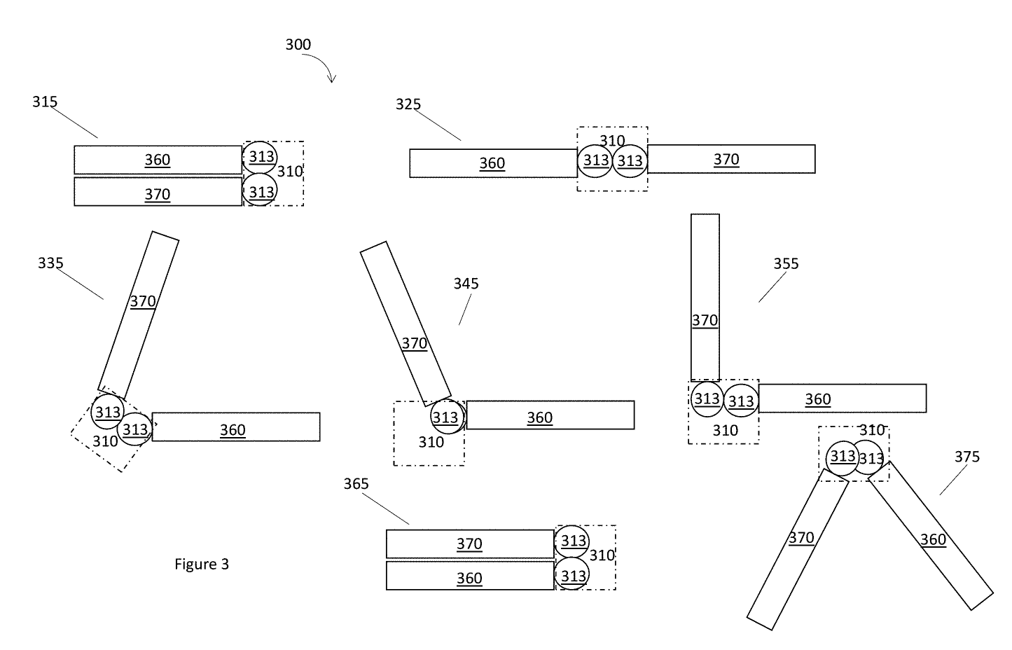

FIG. 3 illustrates various configurations of a computing system 300 formed by attaching a first computing part 360 and a second computing part 370 to a spine assembly 310, in accordance with various embodiments. In embodiments, the computing system 300, the computing part 360, the computing part 370, and the spine assembly 310 may be examples of the computing system 100, the computing part 160, the computing part 170, and the spine assembly 110, as shown in FIG. 1; or as examples of the computing system 200, the computing part 260, the computing part 270, and the spine assembly 210, as shown in FIG. 2.

In this example, the computing system 300 includes the computing part 360 and the computing part 370 that are attached to the spine assembly 310. The spine assembly 310 further includes a rotation hinge 313. The computing part 360 or the computing part 370 may rotate around the rotation hinge 313 of the spine assembly 310 from a first position to a second position to form various configurations. A configuration may refer to a position, an arrangement, or an orientation.

In embodiments, the computing system 300 may be in a configuration 315 that is a closed landscape clamshell configuration; a configuration 325 that is a flat configuration; a configuration 335, a configuration 345, a configuration 355, which may be an open clamshell configuration or a tablet configuration; or a configuration 365 that is rotated 360 degrees compared to the configuration 315. The computing system 300 may be in a configuration 375. As examples, the computing system 300 in configuration 375 may be used for multi-user gaming applications, when a user would like to display a presentation to a small audience, or the like. The computing system 300 in configuration 315 and 365 may be used for travel. The computing system 300 in configuration 325 may be used for travel may be used for a dual-display eReader. The item computing system 300 in configuration 355 may be used for a laptop configuration. The various example use cases described previously are meant to be illustrative, and should not be construed as precluding other uses for the aforementioned configurations.

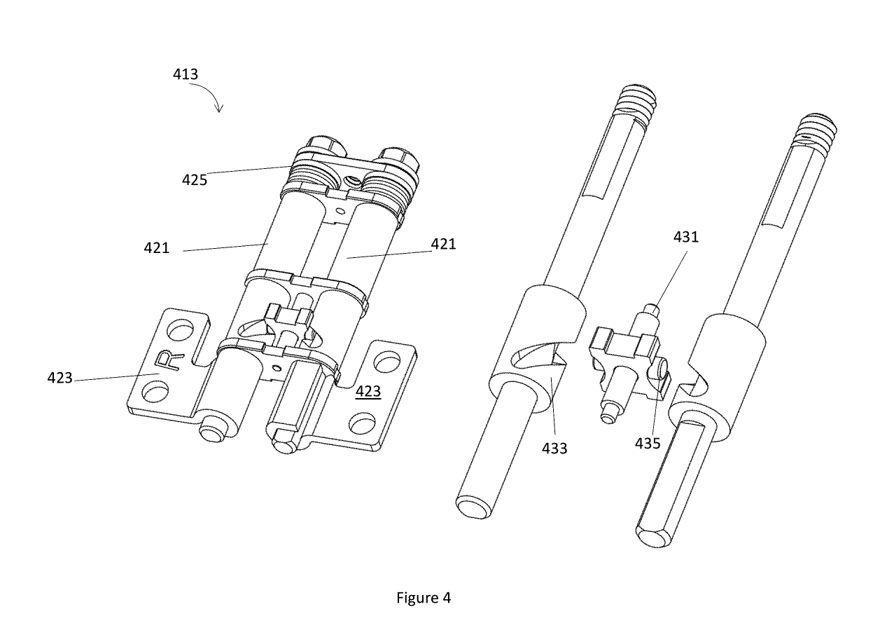

FIG. 4 illustrates an example rotation hinge 413 of a spine assembly, in accordance with various embodiments. In embodiments, the rotation hinge 413 may be an example of the rotation hinge 113 as shown in FIG. 1, the rotation hinge 213 as shown in FIG. 2, or the rotation hinge 313 as shown in FIG. 3. In embodiments, the rotation hinge 413 may be a 360 degree micro hinge including orbital axles 421, mounting brackets 423, torque elements 425, an axis for slider 431, an orbital grooves 433, and a slider pin 435. There may be other additional components of the rotation hinge 413, not shown.

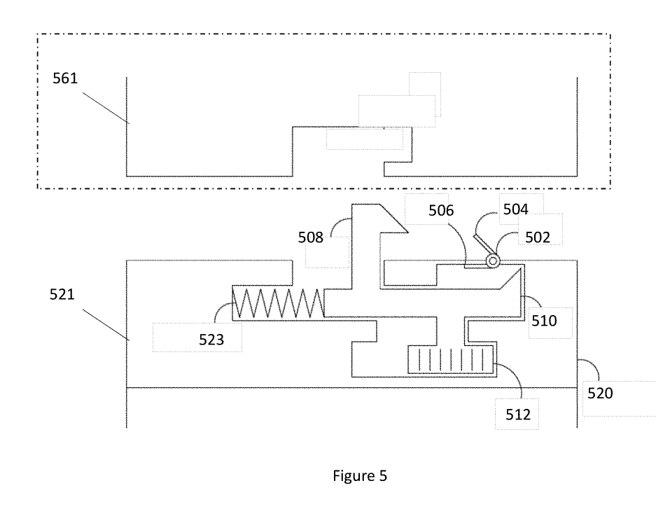

FIG. 5 illustrates an example mechanical attachment coupler 521 of a spine assembly, in accordance with various embodiments. In embodiments, the mechanical attachment coupler 521 may be an example of the mechanical attachment coupler 121 or the mechanical attachment coupler 122 of the spine assembly 110 as shown in FIG. 1. The mechanical attachment coupler 521 may be a hook latch assembly, and may be coupled to a mechanical attachment coupler 561, which may be an example of the mechanical attachment coupler 161 of the computing part 160, or an example of the mechanical attachment coupler 171 of the computing part 170

In embodiments, the mechanical attachment coupler 521 may have a cradle portion 520, a first spring 523, shown here has a coil compression spring, a second spring 502, shown with two extruding portions (504 and 506) from the spring, a first hook tab 508 that extrudes from the cradle portion 520, a second hook tab 510 internal to the cradle portion 520, and a slider mechanism 512 that a user can slide between at least two positions with, for example, a finger. In some embodiments, he first hook tab 508, the slider mechanism 512, and a portion of the second spring 502 may be visible to a user. In many embodiments, the second spring 502 may be in a rest position when the two extruding portions 504 and 506 are extruding at angles apart from each other.

As shown in FIG. 5, the mechanical attachment coupler 521 may be at a rest position because the first spring 523 is in a resting position, referred to as the closed (e.g., latched) position. The first spring 523, when compressed will exert force to return the mechanical attachment coupler 521 to the closed position. Without any other intervening circumstances, the first spring 523 would cause the mechanism to return to this position. Although, the slider mechanism 512, under the force of a user's finger, can be used to override this first spring force and move the entire assembly to an open position. Additionally, the second spring 502 may also be at rest when the extruding portion 504 extrudes from the cradle portion 520 of the device.

In embodiments, the mechanical attachment coupler 521 may be an example, and are not limiting. There may be other forms of mechanical attachment coupler within a spine assembly. For example, a mechanical attachment coupler may include a component selected from a detachable latch, a pin coupler, or a quick coupler.

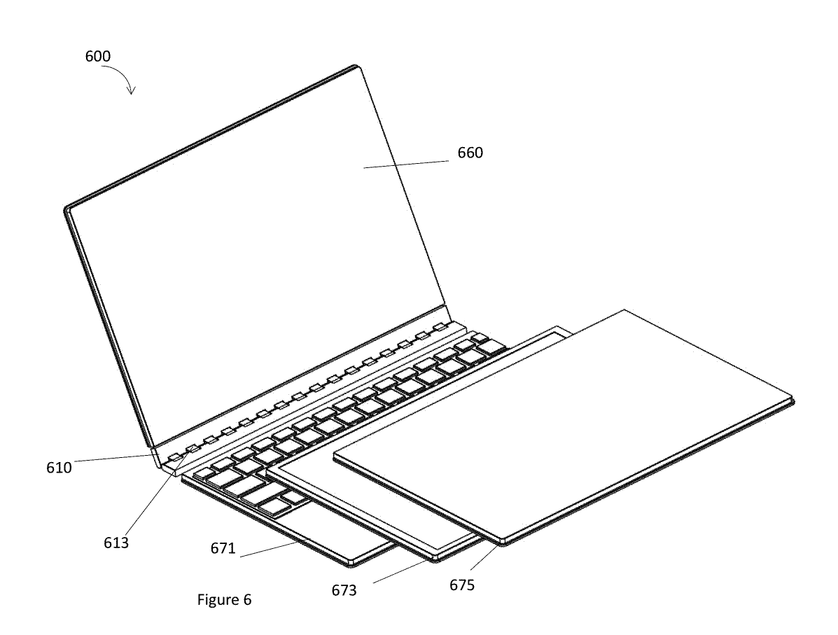

FIG. 6 illustrates an example computing apparatus 600 including three or more computing parts, e.g., a computing part 660, a computing part 671, a computing part 673, and a computing part 675, where two computing parts may be attached to a spine assembly 610, in accordance with various embodiments. In embodiments, the computing part 660, the computing part 671, the computing part 673, the computing part 675, and the spine assembly 610 may be examples of the computing part 160, the computing part 170, and the spine assembly 110, as shown in FIG. 1; or as examples of the computing system 200, the computing part 260, the computing part 270, and the spine assembly 210, as shown in FIG. 2.

In embodiments, the computing apparatus 600 includes the computing part 660, the computing part 671, the computing part 673, the computing part 675, to be attached to the spine assembly 610. A first computing part and a second computing part may be selected from the computing part 660, the computing part 671, the computing part 673, the computing part 675, and attached to the spine assembly 610. The spine assembly 610 may include a rotation hinge 613 located at the middle of the spine assembly 610. When attached, the first computing part or the second computing part may rotate around the rotation hinge 613 of the spine assembly 610 from a first position to a second position.

In embodiments, any computing part of the computing part 660, the computing part 671, the computing part 673, the computing part 675 may include an electronic interface and a mechanical attachment coupler to be coupled to the spine assembly 610. In addition, certain functions may be implemented in some specific computing parts and may be configured to work with multiple other computing parts to form different computing systems.

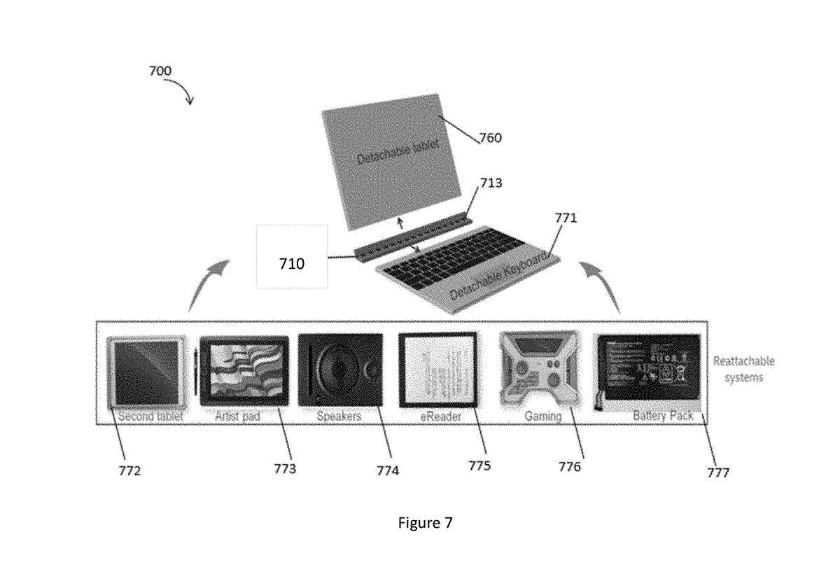

FIG. 7 illustrates an example computing apparatus 700 including three or more computing parts, e.g., a computing part 760, a computing part 771, a computing part 772, a computing part 773, a computing part 774, a computing part 775, a computing part 776, and a computing part 777, where two computing parts may be attached to a spine assembly 710, in accordance with various embodiments. In embodiments, the computing part 760, the computing part 771, the computing part 772, the computing part 773, the computing part 774, the computing part 775, the computing part 776, the computing part 777, and the spine assembly 710 may be examples of the computing part 160, the computing part 170, and the spine assembly 110, as shown in FIG. 1; or as examples of the computing system 200, the computing part 260, the computing part 270, and the spine assembly 210, as shown in FIG. 2.

In embodiments, the computing apparatus 700 includes the computing part 760, the computing part 771, the computing part 772, the computing part 773, the computing part 774, the computing part 775, the computing part 776, the computing part 777, to be attached to the spine assembly 710. A first computing part and a second computing part may be selected from the computing part 760, the computing part 771, the computing part 772, the computing part 773, the computing part 774, the computing part 775, the computing part 776, the computing part 777, and attached to the spine assembly 710. When attached, the first computing part or the second computing part may rotate around the rotation hinge 713 of the spine assembly 710 from a first position to a second position.

In embodiments, certain functions may be implemented in some specific computing parts and may be configured to work with multiple other computing parts to form different computing systems. For example, the first computing part or the second computing part selected from the computing part 760, the computing part 771, the computing part 772, the computing part 773, the computing part 774, the computing part 775, the computing part 776, the computing part 777, may include a computing part of a 2-in-1 system, an artist pad, an eReader, a wearable device, a smartphone, a computer tablet, a laptop, a game controller, a set-top box, a speaker, a battery pack, an infotainment console, or an Internet of Things (IoT) device, or an in-vehicle automotive system.

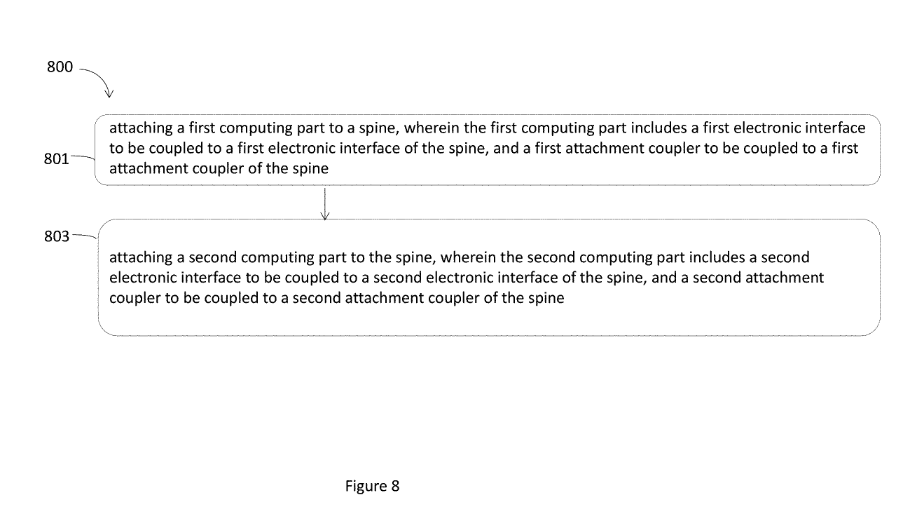

FIG. 8 illustrates an example process 800 for forming a computing system by attaching a first computing part and a second computing part to a spine assembly, in accordance with various embodiments. In embodiments, the process 800 may be a process to form the computing system 100 by attaching the computing part 160 and the computing part 170 to the spine assembly 110 as shown in FIG. 1, to form the computing system 200 by attaching the computing part 260 and the computing part 270 to the spine assembly 210 as shown in FIG. 2, or to form the computing system 300 by attaching the computing part 360 and the computing part 370 to the spine assembly 310 as shown in FIG. 3.

The process 800 may start at an interaction 801. During the interaction 801, a first computing part may be attached to a spine assembly. The first computing part may include a first electronic interface to be coupled to a first electronic interface of the spine assembly, and a first mechanical attachment coupler to be coupled to a first mechanical attachment coupler of the spine assembly. For example, during the interaction 601, the computing part 260 may be attached to the spine assembly 210. The computing part 260 may include the electronic interface 263 to be coupled to the electronic interface 223 of the spine assembly 210, and the mechanical attachment coupler 261 to be coupled to the mechanical attachment coupler 221 of the spine assembly.

During an interaction 803, a second computing part may be attached to the spine assembly. The second computing part may include a second electronic interface to be coupled to a second electronic interface of the spine assembly, and a second mechanical attachment coupler to be coupled to a second mechanical attachment coupler of the spine assembly. For example, during the interaction 803, the computing part 270 may be attached to the spine assembly 210. The computing part 270 may include the electronic interface 273 to be coupled to the electronic interface 224 of the spine assembly 210, and the mechanical attachment coupler 271 to be coupled to the mechanical attachment coupler 222 of the spine assembly. The computing part 260 or the computing part 270 may rotate around the rotation hinge 213 of the spine assembly 210 from a first position to a second position.

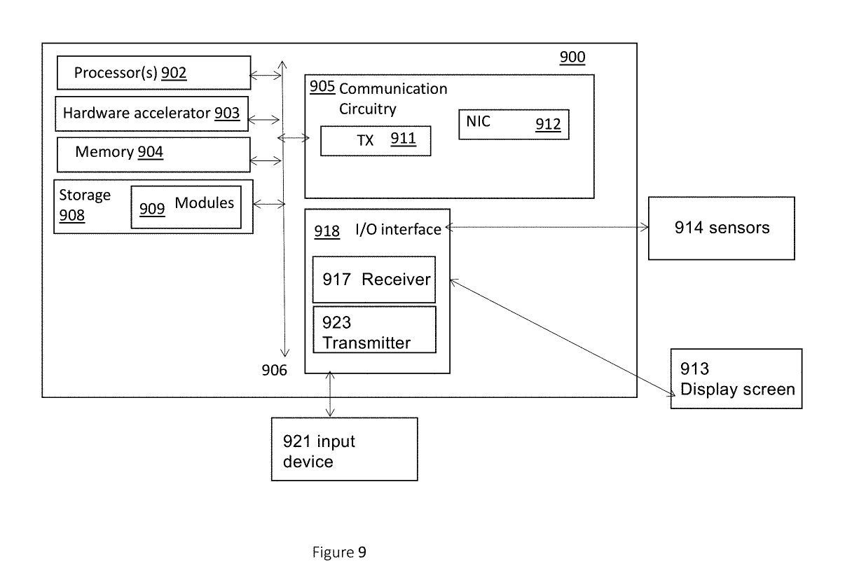

FIG. 9 illustrates an example device suitable for use to practice various aspects of the present disclosure, in accordance with various embodiments. The device 900 may be used to implement functions of the computing system 100, the computing system 200, the computing system 300, the computing apparatus 600, or the computing apparatus 700. As shown, the device 900 may include one or more processors 902, each having one or more processor cores, or and optionally, a hardware accelerator 903 (which may be an ASIC or a FPGA). In alternate embodiments, the hardware accelerator 903 may be part of processor 902, or integrated together on a SOC. Additionally, the device 900 may include a memory 904, which may be any one of a number of known persistent storage medium, and a data storage circuitry 908 including modules 909. In addition, the 900 may include an I/O interface 918, coupled to one or more sensors 914. Furthermore, the device 900 may include communication circuitry 905 including a transceiver (Tx) 911, and network interface controller (NIC) 912. The elements may be coupled to each other via system bus 906, which may represent one or more buses. In the case of multiple buses, they may be bridged by one or more bus bridges (not shown).

In addition, the device 900 may include a display screen 913, and an input device 921. Furthermore, the I/O interface 918 may include a transmitter 923 and a receiver 917. In embodiments, the display screen 913, the off-screen input device 921, and other components shown in FIG. 9, may be included in a computing part, e.g., the computing part 160, the computing part 170, the computing part 260, the computing part 270, the computing part 360, the computing part 370, the computing part 660, the computing part 671, the computing part 673, the computing part 675, the computing part 760, the computing part 771, the computing part 772, the computing part 773, the computing part 774, the computing part 775, the computing part 776, the computing part 777.

In embodiments, the processor(s) 902 (also referred to as “processor circuitry 902”) may be one or more processing elements configured to perform basic arithmetical, logical, and input/output operations by carrying out instructions. Processor circuitry 902 may be implemented as a standalone system/device/package or as part of an existing system/device/package. The processor circuitry 902 may be one or more microprocessors, one or more single-core processors, one or more multi-core processors, one or more multithreaded processors, one or more GPUs, one or more ultra-low voltage processors, one or more embedded processors, one or more DSPs, one or more FPDs (hardware accelerators) such as FPGAs, structured ASICs, programmable SoCs (PSoCs), etc., and/or other processor or processing/controlling circuit. The processor circuitry 902 may be a part of a SoC in which the processor circuitry 902 and other components discussed herein are formed into a single IC or a single package. As examples, the processor circuitry 902 may include one or more Intel Pentium®, Core®, Xeon®, Atom®, or Core M® processor(s); Advanced Micro Devices (AMD) Accelerated Processing Units (APUs), Epyc®, or Ryzen® processors; Apple Inc. A series, S series, W series, etc. processor(s); Qualcomm Snapdragon® processor(s); Samsung Exynos® processor(s); and/or the like.

In embodiments, the processor circuitry 902 may include a sensor hub, which may act as a coprocessor by processing data obtained from the one or more sensors 914. The sensor hub may include circuitry configured to integrate data obtained from each of the one or more sensors 914 by performing arithmetical, logical, and input/output operations. In embodiments, the sensor hub may capable of timestamping obtained sensor data, providing sensor data to the processor circuitry 902 in response to a query for such data, buffering sensor data, continuously streaming sensor data to the processor circuitry 902 including independent streams for each sensor of the one or more sensors 914, reporting sensor data based upon predefined thresholds or conditions/triggers, and/or other like data processing functions.

In embodiments, the memory 904 (also referred to as “memory circuitry 904” or the like) may be circuitry configured to store data or logic for operating the computer device 900. The memory circuitry 904 may include number of memory devices may be used to provide for a given amount of system memory. As examples, the memory circuitry 904 can be any suitable type, number and/or combination of volatile memory devices (e.g., random access memory (RAM), dynamic RAM (DRAM), static RAM (SAM), etc.) and/or non-volatile memory devices (e.g., read-only memory (ROM), erasable programmable read-only memory (EPROM), electrically erasable programmable read-only memory (EEPROM), flash memory, antifuses, etc.) that may be configured in any suitable implementation as are known. In various implementations, individual memory devices may be formed of any number of different package types, such as single die package (SDP), dual die package (DDP) or quad die package (Q17P), dual inline memory modules (DIMMs) such as microDIMMs or MiniDIMMs, and/or any other like memory devices. To provide for persistent storage of information such as data, applications, operating systems and so forth, the memory circuitry 904 may include one or more mass-storage devices, such as a solid state disk drive (SSDD); flash memory cards, such as SD cards, microSD cards, xD picture cards, and the like, and USB flash drives; on-die memory or registers associated with the processor circuitry 902 (for example, in low power implementations); a micro hard disk drive (HDD); three dimensional cross-point (3D)(POINT) memories from Intel® and Micron®, etc.

Where FPDs are used, the processor circuitry 902 and memory circuitry 904 (and/or data storage circuitry 908) may comprise logic blocks or logic fabric, memory cells, input/output (I/O) blocks, and other interconnected resources that may be programmed to perform various functions of the example embodiments discussed herein. The memory cells may be used to store data in lookup-tables (LUTs) that are used by the processor circuitry 902 to implement various logic functions. The memory cells may include any combination of various levels of memory/storage including, but not limited to, EPROM, EEPROM, flash memory, SRAM, antifuses, etc.

In embodiments, the data storage circuitry 908 (also referred to as “storage circuitry 908” or the like), with shared or respective controllers, may provide for persistent storage of information such as modules 909, operating systems, etc. The data storage circuitry 908 may be implemented as solid state drives (SSDs); solid state disk drive (SSDD); serial AT attachment (SATA) storage devices (e.g., SATA SSDs); flash drives; flash memory cards, such as SD cards, microSD cards, xD picture cards, and the like, and USB flash drives; three-dimensional cross-point (3D Xpoint) memory devices; on-die memory or registers associated with the processor circuitry 902; hard disk drives (HDDs); micro HDDs; resistance change memories; phase change memories; holographic memories; or chemical memories; among others. As shown, the data storage circuitry 908 is included in the computer device 900; however, in other embodiments, the data storage circuitry 908 may be implemented as one or more devices separated from the other elements of computer device 900.

In some embodiments, the data storage circuitry 908 may include an operating system (OS) (not shown), which may be a general purpose operating system or an operating system specifically written for and tailored to the computer device 900. The OS may include one or more drivers, libraries, and/or application programming interfaces (APIs), which provide program code and/or software components for modules 909 and/or control system configurations to control and/or obtain/process data from the one or more sensors 914.

The modules 909 may be software modules/components used to perform various functions of the computer device 900 and/or to carry out functions of the example embodiments discussed herein. In embodiments where the processor circuitry 902 and memory circuitry 904 includes hardware accelerators (e.g., FPGA cells, the hardware accelerator 903) as well as processor cores, the hardware accelerators (e.g., the FPGA cells) may be pre-configured (e.g., with appropriate bit streams, logic blocks/fabric, etc.) with the logic to perform some functions of the embodiments herein (in lieu of employment of programming instructions to be executed by the processor core(s)). For example, the modules 909 may comprise logic for the corresponding entities discussed with regard to the display screen 913, the on-screen input device 915, the on-screen input interface controller 911, the off-screen input device 921, the transmitter 923, and the receiver 917.

The components of computer device 900 may communicate with one another over the bus 906. The bus 906 may include any number of technologies, such as a Local Interconnect Network (LIN); industry standard architecture (ISA); extended ISA (EISA); PCI; PCI extended (PCIx); PCIe; an Inter-Integrated Circuit (I2C) bus; a Parallel Small Computer System Interface (SPI) bus; Common Application Programming Interface (CAPI); point to point interfaces; a power bus; a proprietary bus, for example, Intel® Ultra Path Interface (UPI), Intel® Accelerator Link (IAL), or some other proprietary bus used in a SoC based interface; or any number of other technologies. In some embodiments, the bus 906 may be a controller area network (CAN) bus system, a Time-Trigger Protocol (TTP) system, or a FlexRay system, which may allow various devices (e.g., the one or more sensors 914, etc.) to communicate with one another using messages or frames.

The communications circuitry 905 may include circuitry for communicating with a wireless network or wired network. For example, the communication circuitry 905 may include transceiver (Tx) 911 and network interface controller (NIC) 912. Communications circuitry 905 may include one or more processors (e.g., baseband processors, modems, etc.) that are dedicated to a particular wireless communication protocol.

NIC 912 may be included to provide a wired communication link to a network and/or other devices. The wired communication may provide an Ethernet connection, an Ethernet-over-USB, and/or the like, or may be based on other types of networks, such as DeviceNet, ControlNet, Data Highway+, PROFIBUS, or PROFINET, among many others. An additional NIC 912 may be included to allow connect to a second network (not shown) or other devices, for example, a first NIC 912 providing communications to the network 150 over Ethernet, and a second NIC 912 providing communications to other devices over another type of network, such as a personal area network (PAN) including a personal computer (PC) device. In some embodiments, the various components of the device 900, such as the one or more sensors 914, etc. may be connected to the processor(s) 902 via the NIC 912 as discussed above rather than via the I/O circuitry 918 as discussed infra.

The Tx 911 may include one or more radios to wirelessly communicate with a network and/or other devices. The Tx 911 may include hardware devices that enable communication with wired networks and/or other devices using modulated electromagnetic radiation through a solid or non-solid medium. Such hardware devices may include switches, filters, amplifiers, antenna elements, and the like to facilitate the communications over the air (OTA) by generating or otherwise producing radio waves to transmit data to one or more other devices, and converting received signals into usable information, such as digital data, which may be provided to one or more other components of computer device 900. In some embodiments, the various components of the device 900, such as the one or more sensors 914, etc. may be connected to the device 900 via the Tx 911 as discussed above rather than via the I/O circuitry 918 as discussed infra. In one example, the one or more sensors 914 may be coupled with device 900 via a short range communication protocol.

The Tx911 may include one or multiple radios that are compatible with any number of 3GPP (Third Generation Partnership Project) specifications, notably Long Term Evolution (LTE), Long Term Evolution-Advanced (LTE-A), Long Term Evolution-Advanced Pro (LTE-A Pro), and Fifth Generation (5G) New Radio (NR). It can be noted that radios compatible with any number of other fixed, mobile, or satellite communication technologies and standards may be selected. These may include, for example, any Cellular Wide Area radio communication technology, which may include e.g. a 5G communication systems, a Global System for Mobile Communications (GSM) radio communication technology, a General Packet Radio Service (GPRS) radio communication technology, or an Enhanced Data Rates for GSM Evolution (EDGE) radio communication technology. Other Third Generation Partnership Project (3GPP) radio communication technology that may be used includes UMTS (Universal Mobile Telecommunications System), FOMA (Freedom of Multimedia Access), 3GPP LTE (Long Term Evolution), 3GPP LTE Advanced (Long Term Evolution Advanced), 3GPP LTE Advanced Pro (Long Term Evolution Advanced Pro)), CDMA2000 (Code division multiple access 2000), CDPD (Cellular Digital Packet Data), Mobitex, 3G (Third Generation), CSD (Circuit Switched Data), HSCSD (High-Speed Circuit-Switched Data), UMTS (3G) (Universal Mobile Telecommunications System (Third Generation)), W-CDMA (UMTS) (Wideband Code Division Multiple Access (Universal Mobile Telecommunications System)), HSPA (High Speed Packet Access), HSDPA (High-Speed Downlink Packet Access), HSUPA (High-Speed Uplink Packet Access), HSPA+(High Speed Packet Access Plus), UMTS-TDD (Universal Mobile Telecommunications System-Time-Division Duplex), TD-CDMA (Time Division-Code Division Multiple Access), TD-SCDMA (Time Division-Synchronous Code Division Multiple Access), 3GPP Rel. 8 (Pre-4G) (3rd Generation Partnership Project Release 8 (Pre-4th Generation)), 3GPP Rel. 9 (3rd Generation Partnership Project Release 9), 3GPP Rel. 10 (3rd Generation Partnership Project Release 10), 3GPP Rel. 11 (3rd Generation Partnership Project Release 11), 3GPP Rel. 12 (3rd Generation Partnership Project Release 12), 3GPP Rel. 13 (3rd Generation Partnership Project Release 13), 3GPP Rel. 14 (3rd Generation Partnership Project Release 14), 3GPP LTE Extra, LTE Licensed-Assisted Access (LAA), UTRA (UMTS Terrestrial Radio Access), E-UTRA (Evolved UMTS Terrestrial Radio Access), LTE Advanced (4G) (Long Term Evolution Advanced (4th Generation)), cdmaOne (2G), CDMA2000 (3G) (Code division multiple access 2000 (Third generation)), EV-DO (Evolution-Data Optimized or Evolution-Data Only), AMPS (1G) (Advanced Mobile Phone System (1st Generation)), TACS/ETACS (Total Access Communication System/Extended Total Access Communication System), D-AMPS (2G) (Digital AMPS (2nd Generation)), PTT (Push-to-talk), MTS (Mobile Telephone System), IMTS (Improved Mobile Telephone System), AMTS (Advanced Mobile Telephone System), OLT (Norwegian for Offentlig Landmobil Telefoni, Public Land Mobile Telephony), MTD (Swedish abbreviation for Mobiltelefonisystem D, or Mobile telephony system D), Autotel/PALM (Public Automated Land Mobile), ARP (Finnish for Autoradiopuhelin, “car radio phone”), NMT (Nordic Mobile Telephony), Hicap (High capacity version of NTT (Nippon Telegraph and Telephone)), CDPD (Cellular Digital Packet Data), Mobitex, DataTAC, iDEN (Integrated Digital Enhanced Network), PDC (Personal Digital Cellular), CSD (Circuit Switched Data), PHS (Personal Handy-phone System), WiDEN (Wideband Integrated Digital Enhanced Network), iBurst, Unlicensed Mobile Access (UMA, also referred to as also referred to as 3GPP Generic Access Network, or GAN standard)), Wireless Gigabit Alliance (WiGig) standard, mmWave standards in general (wireless systems operating at 10-90 GHz and above such as WiGig, IEEE 802.11ad, IEEE 802.11ay, and the like. In addition to the standards listed above, any number of satellite uplink technologies may be used for the uplink transceiver, including, for example, radios compliant with standards issued by the ITU (International Telecommunication Union), or the ETSI (European Telecommunications Standards Institute), among others. The examples provided herein are thus understood as being applicable to various other communication technologies, both existing and not yet formulated. Implementations, components, and details of the aforementioned protocols may be those known in the art and are omitted herein for the sake of brevity.

The input/output (I/O) interface 918 may include circuitry, such as an external expansion bus (e.g., Universal Serial Bus (USB), FireWire, Thunderbolt, PCI/PCIe/PCIx, etc.), used to connect computer device 900 with external components/devices, such as one or more sensors 914, etc. I/O interface circuitry 918 may include any suitable interface controllers and connectors to interconnect one or more of the processor circuitry 902, memory circuitry 904, data storage circuitry 908, communication circuitry 905, and the other components of computer device 900. The interface controllers may include, but are not limited to, memory controllers, storage controllers (e.g., redundant array of independent disk (RAID) controllers, baseboard management controllers (BMCs), input/output controllers, host controllers, etc. The connectors may include, for example, busses (e.g., bus 906), ports, slots, jumpers, interconnect modules, receptacles, modular connectors, etc. The I/O circuitry 918 may couple the device 900 with the one or more sensors 914, etc. via a wired connection, such as using USB, FireWire, Thunderbolt, RCA, a video graphics array (VGA), a digital visual interface (DVI) and/or mini-DVI, a high-definition multimedia interface (HDMI), an S-Video, and/or the like.

The one or more sensors 914 may be any device configured to detect events or environmental changes, convert the detected events into electrical signals and/or digital data, and transmit/send the signals/data to the computer device 900. Some of the one or more sensors 914 may be sensors used for providing computer-generated sensory inputs. Some of the one or more sensors 914 may be sensors used for motion and/or object detection. Examples of such one or more sensors 914 may include, inter alia, charged-coupled devices (CCD), Complementary metal-oxide-semiconductor (CMOS) active pixel sensors (APS), lens-less image capture devices/cameras, thermographic (infrared) cameras, Light Imaging Detection And Ranging (LIDAR) systems, and/or the like. In some implementations, the one or more sensors 914 may include a lens-less image capture mechanism comprising an array of aperture elements, wherein light passing through the array of aperture elements define the pixels of an image. In embodiments, the motion detection one or more sensors 914 may be coupled with or associated with light generating devices, for example, one or more infrared projectors to project a grid of infrared light onto a scene, where an infrared camera may record reflected infrared light to compute depth information.

Some of the one or more sensors 914 may be used for position and/or orientation detection, ambient/environmental condition detection, and the like. Examples of such one or more sensors 914 may include, inter alia, microelectromechanical systems (MEMS) with piezoelectric, piezoresistive and/or capacitive components, which may be used to determine environmental conditions or location information related to the computer device 900. In embodiments, the MEMS may include 3-axis accelerometers, 3-axis gyroscopes, and/or magnetometers. In some embodiments, the one or more sensors 914 may also include one or more gravimeters, altimeters, barometers, proximity sensors (e.g., infrared radiation detector(s) and the like), depth sensors, ambient light sensors, thermal sensors (thermometers), ultrasonic transceivers, and/or the like.

Each of these elements, e.g., one or more processors 902, the hardware accelerator 903, the memory 904, the data storage circuitry 908 including the modules 909, the input/output interface 918, the one or more sensors 914, the communication circuitry 905 including the Tx 911, and the NIC 912, and the system bus 906, may perform its conventional functions known in the art. In addition, they may be employed to store and host execution of programming instructions implementing the operations associated with operations to be performed by an apparatus for computer assisted or autonomous driving, as described in connection with FIGS. 1-8, and/or other functions that provides the capability of the embodiments described in the current disclosure. The various elements may be implemented by assembler instructions supported by processor(s) 902 or high-level languages, such as, for example, C, that can be compiled into such instructions. Operations associated with the device 900 not implemented in software may be implemented in hardware, e.g., via hardware accelerator 903.

The number, capability and/or capacity of these elements 902-923 may vary, depending on the number of other devices the device 900 is configured to support. Otherwise, the constitutions of elements 902-923 are known, and accordingly will not be further described.

As will be appreciated by one skilled in the art, the present disclosure may be embodied as methods or computer program products. Accordingly, the present disclosure, in addition to being embodied in hardware as earlier described, may take the form of an entirely software embodiment (including firmware, resident software, micro-code, etc.) or an embodiment combining software and hardware aspects that may all generally be referred to as a “circuit,” “module,” or “system.”

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Embodiments may be implemented as a computer process, a computing system or as an article of manufacture such as a computer program product of computer readable media. The computer program product may be a computer storage medium readable by a computer system and encoding a computer program instructions for executing a computer process.

The corresponding structures, material, acts, and equivalents of all means or steps plus function elements in the claims below are intended to include any structure, material or act for performing the function in combination with other claimed elements are specifically claimed. The description of the present disclosure has been presented for purposes of illustration and description, but is not intended to be exhaustive or limited to the disclosure in the form disclosed. Many modifications and variations will be apparent to those of ordinary skill without departing from the scope and spirit of the disclosure. The embodiment are chosen and described in order to best explain the principles of the disclosure and the practical application, and to enable others of ordinary skill in the art to understand the disclosure for embodiments with various modifications as are suited to the particular use contemplated.

Thus various example embodiments of the present disclosure have been described including, but are not limited to:

Example 1 may include a spine assembly for a computing system, comprising: a first attachment subassembly comprising a first mechanical attachment coupler and a first electronic interface, the first electronic interface and the first mechanical attachment coupler to be coupled to a first computing part of the computing system; a second attachment subassembly comprising a second mechanical attachment coupler and a second electronic interface, the second electronic interface and the second mechanical attachment coupler to be coupled to a second computing part of the computing system; and a rotation hinge coupled to the first attachment subassembly and the second attachment subassembly, wherein the first attachment subassembly or the second attachment subassembly is to rotate around the rotation hinge from a first position to a second position.

Example 2 may include the spine assembly of example 1 and/or some other examples herein, further comprising: a housing including the rotation hinge, the first attachment subassembly, or the second attachment subassembly.

Example 3 may include the spine assembly of example 2 and/or some other examples herein, further comprising: a circuitry coupled to the housing, the circuitry to be coupled to the first computing part or the second computing part.

Example 4 may include the spine assembly of example 1 and/or some other examples herein, wherein the computing system is switchable from a first configuration to a second configuration, wherein the first configuration or the second configuration is a configuration selected from a closed landscape clamshell configuration, an open clamshell configuration, a flat configuration, or a tablet configuration.

Example 5 may include the spine assembly of example 1 and/or some other examples herein, wherein the rotation hinge includes a hinge selected from a base bracket hinge, a damping hinge, a display hinge, a friction hinge, a revolving hinge, a clamshell hinge, a free stop hinge, a 45° hinge, a 90° hinge, or a 360 degree micro hinge including orbital axles, mounting brackets, and a slider pin.

Example 6 may include a computing apparatus, comprising: a first computing part, and a second computing part, wherein the first computing part and the second computing part are to be attached to a spine assembly, the first computing part includes a first electronic interface and a first mechanical attachment coupler to be coupled to the spine assembly, the second computing part includes a second electronic interface and a second mechanical attachment coupler to be coupled to the spine assembly, and wherein the first computing part or the second computing part is to rotate around a rotation hinge of the spine assembly from a first position to a second position.

Example 7 may include the computing apparatus of example 6 and/or some other examples herein, further comprising: a third computing part to be attachable to the spine assembly in lieu of either the first computing part or the second computing part.

Example 8 may include the computing apparatus of example 6 and/or some other examples herein, wherein the first computing part or the second computing part includes a computing part selected from a processor, a storage device, an input or output peripheral device, or a power source.

Example 9 may include the computing apparatus of example 6 and/or some other examples herein, wherein the first computing part or the second computing part includes an input or output peripheral device selected from a keyboard, a printer, a speaker, a projector, a sound card, a video card, a camera, a video, a graphics tablet, a scanner, a joystick, a microphone, a mouse, a stylus, a virtual keyboard, a clock, a trackball, a resistive touchscreen, a capacitive touchscreen, an infrared touchscreen, an optical touchscreen, a display, a light-emitting diode (LED) display, a liquid crystal display (LCD), a thin film transistor liquid crystal display (TFT-LCD), a digital light processing (DLP) display, a plasma display, an electroluminescent panel, an organic light-emitting diode (OLED) display, or an electronic paper.

Example 10 may include the computing apparatus of example 6 and/or some other examples herein, wherein the first mechanical attachment coupler or the second mechanical attachment coupler includes a component selected from a detachable latch, a pin coupler, or a quick coupler.

Example 11 may include the computing apparatus of example 6 and/or some other examples herein, wherein the first electronic interface or the second electronic interface includes an interface according to a near field communication (NFC) protocol, a wireless personal area network (WPAN) protocol, a mobile body area networks (MBAN) protocol, an infrared protocol, a Bluetooth® protocol, a ZigBee protocol, a Z-Wave protocol, a dedicated short range communications (DSRC) protocol, a universal serial bus (USB) protocol, a Miracast protocol, a wireless display (WiDi) protocol, a high-bandwidth digital content protection (HDCP) protocol, a user input back channel (UIBC), a mobile industry processor interface display serial interface (MIPI-DSI) protocol, a high-definition multimedia interface (HDMI) protocol, a display port (DP) protocol, a serial peripheral interface (SPI) protocol, a scalable coherent interface (SCI) protocol, a small computer system interface (SCSI) protocol, a peripheral component interconnect (PCI) protocol, or an inter-integrated circuit (I²C) protocol.

Example 12 may include the computing apparatus of example 6 and/or some other examples herein, wherein the computing apparatus is one selected from a 2-in-1 system, an artist pad, an eReader, a wearable device, a smartphone, a computer tablet, a laptop, a game controller, a set-top box, an infotainment console, or an Internet of Things (IoT) device, or an in-vehicle automotive system.

Example 13 may include the computing apparatus of example 6 and/or some other examples herein, wherein the first computing part is to communicate through the first electronic interface with a circuitry of the spine assembly when the first computing part is attached to the spine assembly.

Example 14 may include a method for forming a computing system, comprising: attaching a first computing part to a spine assembly, wherein the first computing part includes a first electronic interface to be coupled to a first electronic interface of the spine assembly, and a first mechanical attachment coupler to be coupled to a first mechanical attachment coupler of the spine assembly; and attaching a second computing part to the spine assembly, wherein the second computing part includes a second electronic interface to be coupled to a second electronic interface of the spine assembly, and a second mechanical attachment coupler to be coupled to a second mechanical attachment coupler of the spine assembly; wherein the first computing part or the second computing part rotates around a rotation hinge of the spine assembly from a first position to a second position.

Example 15 may include the method of example 14 and/or some other examples herein, wherein the first computing part is to communicate through the first electronic interface with a circuitry of the spine assembly.

Example 16 may include the method of example 14 and/or some other examples herein, wherein the first computing part or the second computing part includes a computing part selected from a processor, a storage device, an input or output peripheral device, or a power source.

Example 17 may include the method of example 14 and/or some other examples herein, wherein the first computing part or the second computing part includes an input or output peripheral device selected from a keyboard, a printer, a speaker, a projector, a sound card, a video card, a camera, a video, a graphics tablet, a scanner, a joystick, a microphone, a mouse, a stylus, a virtual keyboard, a clock, a trackball, a resistive touchscreen, a capacitive touchscreen, an infrared touchscreen, an optical touchscreen, a display, a light-emitting diode (LED) display, a liquid crystal display (LCD), a thin film transistor liquid crystal display (TFT-LCD), a digital light processing (DLP) display, a plasma display, an electroluminescent panel, an organic light-emitting diode (OLED) display, or an electronic paper.

Example 18 may include the method of example 14 and/or some other examples herein, wherein the first mechanical attachment coupler of the spine assembly or the second mechanical attachment coupler of the spine assembly includes a component selected from a detachable latch, a pin coupler, or a quick coupler.

Example 19 may include the method of example 14 and/or some other examples herein, wherein the first electronic interface, the second electronic interface, the first electronic interface of the spine assembly, or the second electronic interface of the spine assembly includes an interface according to a near field communication (NFC) protocol, a wireless personal area network (WPAN) protocol, a mobile body area networks (MBAN) protocol, an infrared protocol, a Bluetooth® protocol, a ZigBee protocol, a Z-Wave protocol, a dedicated short range communications (DSRC) protocol, a universal serial bus (USB) protocol, a Miracast protocol, a wireless display (WiDi) protocol, a high-bandwidth digital content protection (HDCP) protocol, a user input back channel (UIBC), a mobile industry processor interface display serial interface (MIPI-DSI) protocol, a high-definition multimedia interface (HDMI) protocol, a display port (DP) protocol, a serial peripheral interface (SPI) protocol, a scalable coherent interface (SCI) protocol, a small computer system interface (SCSI) protocol, a peripheral component interconnect (PCI) protocol, or an inter-integrated circuit (I²C) protocol.

Example 20 may include the method of example 14 and/or some other examples herein, wherein the computing system is one selected from a 2-in-1 system, an artist pad, an eReader, a wearable device, a smartphone, a computer tablet, a laptop, a game controller, a set-top box, an infotainment console, or an Internet of Things (IoT) device, or an in-vehicle automotive system.

Example 21 may include a computing apparatus, comprising: three or more computing parts, wherein a first computing part and a second computing part selected from the three or more computing parts are to be attached to a spine assembly, the first computing part includes a first electronic interface and a first mechanical attachment coupler to be coupled to the spine assembly, the second computing part includes a second electronic interface and a second mechanical attachment coupler to be coupled to the spine assembly, and wherein the first computing part or the second computing part rotates around a rotation hinge of the spine assembly from a first position to a second position.

Example 22 may include the computing apparatus of example 21 and/or some other examples herein, wherein the first electronic interface or the second electronic interface includes an interface according to a near field communication (NFC) protocol, a wireless personal area network (WPAN) protocol, a mobile body area networks (MBAN) protocol, an infrared protocol, a Bluetooth® protocol, a ZigBee protocol, a Z-Wave protocol, a dedicated short range communications (DSRC) protocol, a universal serial bus (USB) protocol, a Miracast protocol, a wireless display (WiDi) protocol, a high-bandwidth digital content protection (HDCP) protocol, a user input back channel (UIBC), a mobile industry processor interface display serial interface (MIPI-DSI) protocol, a high-definition multimedia interface (HDMI) protocol, a display port (DP) protocol, a serial peripheral interface (SPI) protocol, a scalable coherent interface (SCI) protocol, a small computer system interface (SCSI) protocol, a peripheral component interconnect (PCI) protocol, or an inter-integrated circuit (I²C) protocol.

Example 23 may include the computing apparatus of example 21 and/or some other examples herein, wherein the first computing part or the second computing part selected from the three or more computing parts includes a computing part of a 2-in-1 system, an artist pad, an eReader, a wearable device, a smartphone, a computer tablet, a laptop, a game controller, a set-top box, an infotainment console, or an Internet of Things (IoT) device, or an in-vehicle automotive system.

Example 24 may include the computing apparatus of example 21 and/or some other examples herein, wherein the first computing part or the second computing part attached to the spine assembly is switchable from a first configuration to a second configuration, wherein the first configuration or the second configuration is a configuration selected from a closed landscape clamshell configuration, an open clamshell configuration, a flat configuration, or a tablet configuration.

Example 25 may include the computing apparatus of example 21 and/or some other examples herein, wherein the first computing part or the second computing part includes a computing part selected from a processor, a storage device, an input or output peripheral device, or a power source.

Although certain embodiments have been illustrated and described herein for purposes of description this application is intended to cover any adaptations or variations of the embodiments discussed herein. Therefore, it is manifestly intended that embodiments described herein be limited only by the claims.

What is claimed is:

1. A spine assembly for a computing system, comprising:
a first attachment subassembly comprising a first mechanical attachment coupler and a first electronic interface, the first electronic interface and the first mechanical attachment coupler to be coupled to a first computing part of the computing system;
a second attachment subassembly comprising a second mechanical attachment coupler and a second electronic interface, the second electronic interface and the second mechanical attachment coupler to be coupled to a second computing part of the computing system; and
a rotation hinge coupled to the first attachment subassembly and the second attachment subassembly, wherein the first attachment subassembly or the second attachment subassembly is to rotate around the rotation hinge from a first position to a second position.

2. The spine assembly of the claim 1, further comprising:
a housing including the rotation hinge, the first attachment subassembly, or the second attachment subassembly.

3. The spine assembly of the claim 2, further comprising:
a circuitry coupled to the housing, the circuitry to be coupled to the first computing part or the second computing part.

4. The spine assembly of the claim 1, wherein the computing system is switchable from a first configuration to a second configuration, wherein the first configuration or the second configuration is a configuration selected from a closed landscape clamshell configuration, an open clamshell configuration, a flat configuration, or a tablet configuration.

5. The spine assembly of the claim 1, wherein the rotation hinge includes a hinge selected from a base bracket hinge, a damping hinge, a display hinge, a friction hinge, a revolving hinge, a clamshell hinge, a free stop hinge, a 45° hinge, a 90° hinge, or a 360 degree micro hinge including orbital axles, mounting brackets, and a slider pin.

6. A computing apparatus, comprising:
a first computing part, and a second computing part, wherein the first computing part and the second computing part are to be attached to a spine assembly, the first computing part includes a first electronic interface and a first mechanical attachment coupler to be coupled to the spine assembly, the second computing part includes a second electronic interface and a second mechanical attachment coupler to be coupled to the spine assembly, and wherein the first computing part or the second computing part is to rotate around a rotation hinge of the spine assembly from a first position to a second position.

7. The computing apparatus of claim 6, further comprising:
a third computing part to be attachable to the spine assembly in lieu of either the first computing part or the second computing part.

8. The computing apparatus of claim 6, wherein the first computing part or the second computing part includes a computing part selected from a processor, a storage device, an input or output peripheral device, or a power source.

9. The computing apparatus of claim 6, wherein the first computing part or the second computing part includes an input or output peripheral device selected from a keyboard, a printer, a speaker, a projector, a sound card, a video card, a camera, a video, a graphics tablet, a scanner, a joystick, a microphone, a mouse, a stylus, a virtual keyboard, a clock, a trackball, a resistive touchscreen, a capacitive touchscreen, an infrared touchscreen, an optical touchscreen, a display, a light-emitting diode (LED) display, a liquid crystal display (LCD), a thin film transistor liquid crystal display (TFT-LCD), a digital light processing (DLP) display, a plasma display, an electroluminescent panel, an organic light-emitting diode (OLED) display, or an electronic paper.

10. The computing apparatus of claim 6, wherein the first mechanical attachment coupler or the second mechanical attachment coupler includes a component selected from a detachable latch, a pin coupler, or a quick coupler.

11. The computing apparatus of claim 6, wherein the first electronic interface or the second electronic interface includes an interface according to a near field communication (NFC) protocol, a wireless personal area network (WPAN) protocol, a mobile body area networks (MBAN) protocol, an infrared protocol, a Bluetooth® protocol, a ZigBee protocol, a Z-Wave protocol, a dedicated short range communications (DSRC) protocol, a universal serial bus (USB) protocol, a Miracast protocol, a wireless display (WiDi) protocol, a high-bandwidth digital content protection (HDCP) protocol, a user input back channel (UIBC), a mobile industry processor interface display serial interface (MIPI-DSI) protocol, a high-definition multimedia interface (HDMI) protocol, a display port (DP) protocol, a serial peripheral interface (SPI) protocol, a scalable coherent interface (SCI) protocol, a small computer system interface (SCSI) protocol, a peripheral component interconnect (PCI) protocol, or an inter-integrated circuit (I²C) protocol.

12. The computing apparatus of claim 6, wherein the computing apparatus is one selected from a 2-in-1 system, an artist pad, an eReader, a wearable device, a smartphone, a computer tablet, a laptop, a game controller, a set-top box, an infotainment console, or an Internet of Things (IoT) device, or an in-vehicle automotive system.

13. The computing apparatus of claim 6, wherein the first computing part is to communicate through the first electronic interface with a circuitry of the spine assembly when the first computing part is attached to the spine assembly.

14. A method for forming a computing system, comprising:
attaching a first computing part to a spine assembly, wherein the first computing part includes a first electronic interface to be coupled to a first electronic interface of the spine assembly, and a first mechanical attachment coupler to be coupled to a first mechanical attachment coupler of the spine assembly; and
attaching a second computing part to the spine assembly, wherein the second computing part includes a second electronic interface to be coupled to a second electronic interface of the spine assembly, and a second mechanical attachment coupler to be coupled to a second mechanical attachment coupler of the spine assembly;
wherein the first computing part or the second computing part rotates around a rotation hinge of the spine assembly from a first position to a second position.

15. The method of claim 14, wherein the first computing part is to communicate through the first electronic interface with a circuitry of the spine assembly.

16. The method of claim 14, wherein the first computing part or the second computing part includes a computing part selected from a processor, a storage device, an input or output peripheral device, or a power source.

17. The method of claim 14, wherein the first computing part or the second computing part includes an input or output peripheral device selected from a keyboard, a printer, a speaker, a projector, a sound card, a video card, a camera, a video, a graphics tablet, a scanner, a joystick, a microphone, a mouse, a stylus, a virtual keyboard, a clock, a trackball, a resistive touchscreen, a capacitive touchscreen, an infrared touchscreen, an optical touchscreen, a display, a light-emitting diode (LED) display, a liquid crystal display (LCD), a thin film transistor liquid crystal display (TFT-LCD), a digital light processing (DLP) display, a plasma display, an electroluminescent panel, an organic light-emitting diode (OLED) display, or an electronic paper.

18. The method of claim 14, wherein the first mechanical attachment coupler of the spine assembly or the second mechanical attachment coupler of the spine assembly includes a component selected from a detachable latch, a pin coupler, or a quick coupler.

19. The method of claim 14, wherein the first electronic interface, the second electronic interface, the first electronic interface of the spine assembly, or the second electronic interface of the spine assembly includes an interface according to a near field communication (NFC) protocol, a wireless personal area network (WPAN) protocol, a mobile body area networks (MBAN) protocol, an infrared protocol, a Bluetooth® protocol, a ZigBee protocol, a Z-Wave protocol, a dedicated short range communications (DSRC) protocol, a universal serial bus (USB) protocol, a Miracast protocol, a wireless display (WiDi) protocol, a high-bandwidth digital content protection (HDCP) protocol, a user input back channel (UIBC), a mobile industry processor interface display serial interface (MIPI-DSI) protocol, a high-definition multimedia interface (HDMI) protocol, a display port (DP) protocol, a serial peripheral interface (SPI) protocol, a scalable coherent interface (SCI) protocol, a small computer system interface (SCSI) protocol, a peripheral component interconnect (PCI) protocol, or an inter-integrated circuit (I²C) protocol.

20. The method of claim 14, wherein the computing system is one selected from a 2-in-1 system, an artist pad, an eReader, a wearable device, a smartphone, a computer tablet, a laptop, a game controller, a set-top box, an infotainment console, or an Internet of Things (IoT) device, or an in-vehicle automotive system.

21. A computing apparatus, comprising:
three or more computing parts, wherein a first computing part and a second computing part selected from the three or more computing parts are to be attached to a spine assembly, the first computing part includes a first electronic interface and a first mechanical attachment coupler to be coupled to the spine assembly, the second computing part includes a second electronic interface and a second mechanical attachment coupler to be coupled to the spine assembly, and wherein the first computing part or the second computing part rotates around a rotation hinge of the spine assembly from a first position to a second position.

22. The computing apparatus of claim 21, wherein the first electronic interface or the second electronic interface includes an interface according to a near field communication (NFC) protocol, a wireless personal area network (WPAN) protocol, a mobile body area networks (MBAN) protocol, an infrared protocol, a Bluetooth® protocol, a ZigBee protocol, a Z-Wave protocol, a dedicated short range communications (DSRC) protocol, a universal serial bus (USB) protocol, a Miracast protocol, a wireless display (WiDi) protocol, a high-bandwidth digital content protection (HDCP) protocol, a user input back channel (UIBC), a mobile industry processor interface display serial interface (MIPI-DSI) protocol, a high-definition multimedia interface (HDMI) protocol, a display port (DP) protocol, a serial peripheral interface (SPI) protocol, a scalable coherent interface (SCI) protocol, a small computer system interface (SCSI) protocol, a peripheral component interconnect (PCI) protocol, or an inter-integrated circuit (I²C) protocol.

23. The computing apparatus of claim 21, wherein the first computing part or the second computing part selected from the three or more computing parts includes a computing part of a 2-in-1 system, an artist pad, an eReader, a wearable device, a smartphone, a computer tablet, a laptop, a game controller, a set-top box, an infotainment console, or an Internet of Things (IoT) device, or an in-vehicle automotive system.

24. The computing apparatus of claim 21, wherein the first computing part or the second computing part attached to the spine assembly is switchable from a first configuration to a second configuration, wherein the first configuration or the second configuration is a configuration selected from a closed landscape clamshell configuration, an open clamshell configuration, a flat configuration, or a tablet configuration.

25. The computing apparatus of claim 21, wherein the first computing part or the second computing part includes a computing part selected from a processor, a storage device, an input or output peripheral device, or a power source.
